(19) United States
(12) Patent Application Publication
(10) Pub. No.: US 2017/0117325 A1
(43) Pub. Date: Apr. 27, 2017

(54) ELECTRONIC DEVICE AND METHOD FOR FABRICATING THE SAME

(71) Applicant: SK hynix Inc., Icheon (KR)

(72) Inventors: Jong-Gi KIM, Icheon (KR); Beom-Yong KIM, Icheon (KR); Kee-Jeung LEE, Icheon (KR)

(21) Appl. No.: 15/141,072

(22) Filed: Apr. 28, 2016

(30) Foreign Application Priority Data
Oct. 21, 2015 (KR) 10-2015-0146588

(51) Int. Cl. H01L 27/24; G06F 3/06; H01L 45/00; H01L 27/22; H01L 43/02; H01L 43/08

(52) U.S. Cl. CPC H01L 27/2409; H01L 43/02; H01L 43/08; H01L 45/08; H01L 45/1226; H01L 45/1253; H01L 45/146; H01L 27/224; G06F 3/0604; G06F 3/0659; G06F 3/0679; H01L 27/11507

(57) ABSTRACT

An electronic device according to an implementation of the disclosed technology is an electronic device including a semiconductor memory, wherein the semiconductor memory includes: interlayer insulating layers and conductive first base layer patterns that are alternatively stacked over a substrate; a dielectric second base layer pattern that is in contact with sidewalls of the interlayer insulating layers; first electrodes that are in contact with sidewalls of the first base layer patterns; a second electrode disposed over outer sidewalls of the first electrodes; and a variable resistance layer pattern interposed between the first electrodes and the second electrode. Each of the first electrodes comprises an alloy that includes first and second elements. The first element is included in the first base layer patterns and the second element is included in the second base layer pattern.

### CROSS-REFERENCE TO RELATED APPLICATIONS

The present application claims priority of Korean Patent Application No. 10-2015-0146588, entitled “ELECTRONIC DEVICE AND METHOD FOR FABRICATING THE SAME” and filed on Oct. 21, 2015, which is incorporated herein by reference in its entirety.

### TECHNICAL FIELD

This patent document relates to memory circuits or devices and their applications in electronic devices or systems.

### BACKGROUND

Recently, as electronic appliances trend toward miniaturization, low power consumption, high performance, multi-functionality, and so on, semiconductor devices capable of storing information in various electronic appliances such as a computer, a portable communication device, and so on have been demanded in the art, and research has been conducted for the semiconductor devices. Such semiconductor devices include semiconductor devices which can store data using a characteristic that they are switched between different resistant states according to an applied voltage or current, for example, an RRAM (resistive random access memory), a PRAM (phase change random access memory), an FRAM (ferroelectric random access memory), an MRAM (magnetic random access memory), an E-fuse, etc.

### SUMMARY

The disclosed technology in this patent document includes memory circuits or devices and their applications in electronic devices or systems and various implementations of an electronic device in which the process for fabricating the electronic device can be easily performed and the characteristics of a variable resistance element can be improved.

In an implementation, an electronic device including a semiconductor memory is provided wherein the semiconductor memory includes: interlayer insulating layers and conductive first base layer patterns that are alternatively stacked over a substrate; a dielectric second base layer pattern that is in contact with sidewalls of the interlayer insulating layers; first electrodes that are in contact with sidewalls of the first base layer patterns; a second electrode disposed over outer sidewalls of the first electrodes; and a variable resistance layer pattern interposed between the first electrodes and the second electrode, wherein each of the first electrodes comprises an alloy that includes first and second elements, the first element being included in the first base layer patterns, and the second element being included in the second base layer pattern.

Implementations of the above electronic device may include one or more the following.

The first base layer patterns include TiN, the second base layer pattern includes AlN, and the first electrodes comprise TiAlN. A width of each of the interlayer insulating layers in a direction is equal to or greater than a width of each of the first base layer patterns in the direction, the direction being substantially parallel to a top surface of the substrate. A width of each of the first electrodes in a direction is equal to or greater than a thickness of the second base layer pattern in the direction, the direction being substantially parallel to a top surface of the substrate. An outer sidewall of each of the first electrodes is substantially coplanar with an outer sidewall of the second base layer pattern. An inner sidewall of each of the first electrodes protrudes more towards a corresponding one of the first base layer patterns than an inner sidewall of the second base layer pattern. The interlayer insulating layers, the first base layer patterns, and the first electrodes extend in a first direction, and the second electrode extends in a second direction such that the second electrode overlaps with the first electrodes and the second base layer pattern, the first direction being parallel to a top surface of the substrate, the second direction being perpendicular to the top surface of the substrate. The second electrode extends in a third direction that intersects with the first direction and that is perpendicular to the second direction. The variable resistance layer pattern overlaps with the second electrode. The variable resistance layer pattern overlaps with the second electrode. A resistance of a portion of the variable resistance layer pattern is switched by formation or removal of a conductive path in the portion of the variable resistance layer pattern according to a voltage or a current applied to a corresponding one of the first electrodes and the second electrode, the portion of the variable resistance layer pattern corresponding to an intersection region of the corresponding one of the first electrodes and the second electrode, and the conductive path being substantially parallel to a top surface of the substrate. The variable resistance layer pattern comprises a combination of two or more patterns and the combination exhibits variable resistance characteristics, and wherein each of the two or more patterns is disposed substantially parallel to an outer sidewall of a corresponding one of the first electrodes. The semiconductor memory further comprises a selection element layer sandwiched between the first electrodes and the variable resistance layer pattern, or between the second electrode and the variable resistance layer pattern. The selection element layer is disposed substantially parallel to an outer sidewall of a corresponding one of the first electrodes. The first base layer patterns comprise a material having a higher etch rate than the first electrodes.

The electronic device may further include a microprocessor which includes: a control unit configured to receive a signal including a command from an outside of the microprocessor, and performs extracting, decoding of the command, or controlling input or output of a signal of the microprocessor; an operation unit configured to perform an operation based on a result that the control unit decodes the command; and a memory unit configured to store data for performing the operation, data corresponding to a result of performing the operation, or an address of data for which the operation is performed, wherein the semiconductor memory is part of the memory unit in the microprocessor.

The electronic device may further include a processor which includes: a core unit configured to perform, based on a command inputted from an outside of the processor, an operation corresponding to the command, by using data; a cache memory unit configured to store data for performing the operation, data corresponding to a result of performing the operation, or an address of data for which the operation is performed; and a bus interface connected between the core unit and the cache memory unit, and configured to transmit data between the core unit and the cache memory unit, wherein the semiconductor memory is part of the cache memory unit in the processor.

The electronic device may further include a processing system which includes: a processor configured to decode a command received by the processor and control an operation for information based on a result of decoding the command; an auxiliary memory device configured to store a program for decoding the command and the information; a main memory device configured to call and store the program and the information from the auxiliary memory device such that the processor can perform the operation using the program and the information when executing the program; and an interface device configured to perform communication between at least one of the processor, the auxiliary memory device and the main memory device and the outside, wherein the semiconductor memory is part of the auxiliary memory device or the main memory device in the processing system.

The electronic device may further include a data storage system which includes: a storage device configured to store data and conserve stored data regardless of power supply; a controller configured to control input and output of data to and from the storage device according to a command inputted form an outside; a temporary storage device configured to temporarily store data exchanged between the storage device and the outside; and an interface configured to perform communication between at least one of the storage device, the controller and the temporary storage device and the outside, wherein the semiconductor memory is part of the storage device or the temporary storage device in the data storage system.

The electronic device may further include a memory system which includes: a memory configured to store data and conserve stored data regardless of power supply; a memory controller configured to control input and output of data to and from the memory according to a command inputted form an outside; a buffer memory configured to buffer data exchanged between the memory and the outside; and an interface configured to perform communication between at least one of the memory, the memory controller and the buffer memory and the outside, wherein the semiconductor memory is part of the memory or the buffer memory in the memory system.

In an implementation, a method for fabricating an electronic device including a semiconductor memory includes: alternately stacking interlayer insulating layers and conductive first base layers over a substrate to form a stack; forming a dielectric second base layer such that the second base layer is in contact with a sidewall of the stack; performing a process for reacting the first base layers with the second base layer to form first electrodes, each of the first electrodes comprising an alloy that includes first and second elements, the first element being included in the first base layers, and the second element being included in the second base layer; forming a variable resistance layer on outer sidewalls of the first electrodes; and forming a conductive layer on a sidewall of the variable resistance layer.

Implementations of the above method may include one or more the following.

The first base layers include TiN, the second base layer includes AlN, and the first electrodes comprise TiAlN. The second base layer has a sufficiently small thickness that portions of the second base layer, which overlap with sidewalls of the first base layers, respectively, substantially completely react with the first base layers, such that the portions of the second base layer are transformed into the first electrodes. A portion of each of the first base layers remains unreacted when the first base layers react with the second base layer. The process for reacting the first base layers with the second base layer is a heat-treatment process. The second base layer is formed over substantially the entire surface of the sidewall of the stack. The variable resistance layer and the conductive layer are formed over substantially the entire surface of the sidewall of the stack. The stack extends in a first direction, and the method further comprises, after forming the conductive layer, etching the conductive layer to form two or more second electrodes that are spaced apart from each other in the first direction, the first direction being parallel to a top surface of the substrate. The method further comprising, after forming the second electrodes, etching at least one of the variable resistance layer and the second base layer exposed by the forming of the second electrodes. The method further comprising: etching the conductive layer to form two or more second electrodes; etching the variable resistance layer to form two or more variable resistance layer patterns; and etching the second base layer to form two or more second base layer patterns.

These and other aspects, implementations and associated advantages are described in greater detail in the drawings, the description and the claims.

### BRIEF DESCRIPTION OF THE DRAWINGS

FIGS. 1 to 5 are perspective views illustrating a method for fabricating a semiconductor device according to an implementation of the disclosed technology.

FIG. 6 illustrates a semiconductor device according to an implementation of the disclosed technology.

FIG. 7 illustrates a semiconductor device according to an implementation of the disclosed technology.

FIG. 8 is an example of configuration diagram of a microprocessor implementing memory circuitry based on the disclosed technology.

FIG. 9 is an example of configuration diagram of a processor implementing memory circuitry based on the disclosed technology.

FIG. 10 is an example of configuration diagram of a system implementing memory circuitry based on the disclosed technology.

FIG. 11 is an example of configuration diagram of a data storage system implementing memory circuitry based on the disclosed technology.

FIG. 12 is an example of configuration diagram of a memory system implementing memory circuitry based on the disclosed technology.

### DETAILED DESCRIPTION

Various examples and implementations of the disclosed technology are described below in detail with reference to the accompanying drawings.

The drawings may not be necessarily to scale and in some instances, proportions of at least some of structures in the drawings may have been exaggerated in order to clearly illustrate certain features of the described examples or implementations. In presenting a specific example in a drawing or description having two or more layers in a multi-layer structure, the relative positioning relationship of such layers or the sequence of arranging the layers as shown reflects a particular implementation for the described or illustrated example and a different relative positioning relationship or sequence of arranging the layers may be possible. In addition, a described or illustrated example of a multi-layer structure may not reflect all layers present in that particular multilayer structure (e.g., one or more additional layers may be present between two illustrated layers). As a specific example, when a first layer in a described or illustrated multi-layer structure is referred to as being “on” or “over” a second layer or “on” or “over” a substrate, the first layer may be directly formed on the second layer or the substrate but may also represent a structure where one or more other intermediate layers may exist between the first layer and the second layer or the substrate.

Implementations of the disclosed technology are directed to a variable resistance element including a variable resistance layer sandwiched between two electrodes. The variable resistance layer included in the variable resistance element can switch between a low-resistance state and a high-resistance state according to a voltage or a current applied to the two electrodes. Thus, the variable resistance element may function as a memory cell that stores different data according to a resistance state thereof.

Herein, it is important to properly select a material to be used for the electrodes in order to ensure desirable characteristics of the variable resistance element. For example, if the variable resistance element includes a TiAlN electrode having a high work function and high resistivity, a current value flowing through the variable resistance element in the high-resistance state can be reduced. As a result, a difference in resistance values between the high-resistance state and the low-resistance state of the variable resistance element can increase to ensure a read margin. In addition, because the TiAlN electrode is less reactive with oxygen and is amorphous, reactions at an interface between the TiAlN electrode and a variable resistance layer that includes a metal oxide can be reduced, and thus loss of oxygen from the variable resistance layer can be reduced. As a result, reliability of the variable resistance element can be improved.

However, due to process limits, it may be difficult to select proper electrode materials. For example, because a TiAlN layer is hardly etched using a conventional etching process, it may be difficult to mass-produce a variable resistance element including the TiAlN electrode.

Implementations of the disclosed technology are intended to address the above-described issue and to provide a semiconductor device and a method for fabricating the same in which fabricating the semiconductor device and selecting electrode materials can be facilitated.

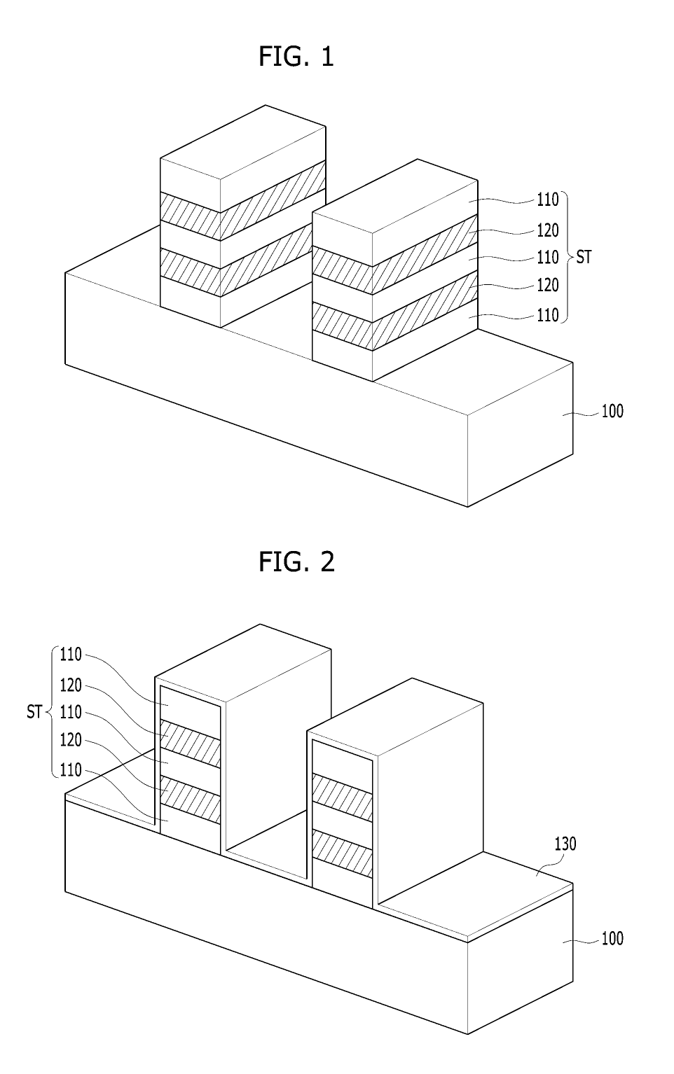

FIGS. 1 to 5 are perspective views illustrating a method for fabricating a semiconductor device according to an implementation of the disclosed technology. The semiconductor device according to this implementation may include a variable resistance element having a horizontal electrode formed of an alloy that includes two or more elements.

The method for fabricating the semiconductor device according to this implementation will now be described.

Referring to FIG. 1, on a substrate 100 having a desirable structure (not shown) formed therein, interlayer insulating layers 110 and conductive first base layers 120 may be alternately stacked to form a stack ST.

The interlayer insulating layers 110 each serve to electrically insulate corresponding one or more of the first base layers 120 from other conductive materials. For example, an interlayer insulating layer 110 electrically insulates a first one of the first base layers 120 from a second one of the first base layers 120, when the first one of the first base layers 120, the interlayer insulating layer 110, and the second one of the first base layers 120 are sequentially stacked in a direction (e.g., a vertical direction with respect to the orientation of FIG. 1) substantially perpendicular to a top surface of the substrate 100. The interlayer insulating layers 110 may include various dielectric materials such as oxides, nitrides, or combinations thereof.

The first base layers 120 are used to form one or more horizontal electrodes as will be described below, and may be formed of a conductive material including one or more of elements included in an alloy that forms the horizontal electrodes. In addition, the first base layers 120 may be formed of a material that is more easily etched than the alloy forming the horizontal electrodes. For example, if the horizontal electrodes are formed of a TiAlN alloy, the first base layers 120 may include TiN. One or more first base layers 120 may be alternately disposed with the interlayer insulating layers 110 in the vertical direction.

The stack ST may extend in a first horizontal direction (or a first direction) that is substantially parallel to the top surface of the substrate 100. Two or more stacks ST may be arranged to be spaced apart from each other along a second horizontal direction (or a second direction) that intersects with the first horizontal direction and that is substantially parallel to the top surface of the substrate 100.

Referring to FIG. 2, a second base layer 130 may be formed over substantially the entire surface of the structure resulting from the process of FIG. 1.

The second base layer 130, together with the first base layers 120, is used to form the horizontal electrodes as will be described below, and may be formed of a dielectric material including one or more elements, which are not included in the first base layers 120, among the elements included in the alloy forming the horizontal electrodes. Furthermore, the second base layer 130 may be formed of a material that is more easily etched than the alloy forming the horizontal electrodes. For example, if each of the horizontal electrodes is formed of a TiAlN alloy and the first base layers 120 include TiN, the second base layer 130 may include AlN. The element, nitrogen N, may be included in both the first and second base layers 120 and 130.

The second base layer 130 may have a sufficiently small thickness that portions of the second base layer 130, which are in contact with corresponding portions of the first base layers 120, respectively, can substantially completely react with the first base layers 120 in a subsequent heat-treatment process, and thus the reacted portions of the second base layer 130 and the contacting portions of the first base layers 120 can be converted into an alloy forming the horizontal electrode.

Although FIG. 2 illustrates that the second base layer 130 is formed over substantially the entire surface of the structure resulting from the process of FIG. 1, the second base layer 130 may have various shapes, as long as it comes into contact with at least a portion of a sidewall of the first base layer 120. In an implementation, the second base layer 130 may be divided into a plurality of line-shaped layers each extending in the second direction. The plurality of line-shaped layers is disposed on sidewalls of one or more stacks ST, and thus adjacent line-shaped layers are spaced apart from each other in the first direction.

Referring to FIG. 3, a heat-treatment process may be performed to make the first base layers 120 react with corresponding portions of the second base layer 130, thereby forming alloy layers that include not only elements included in the first base layers 120, but also elements included in the second base layer 130. For example, if the first base layers 120 include TiN and the second base layer 130 includes AlN, a TiAlN alloy layer may be formed. More specifically, in terms of composition, vertical portions of the second base layer 130, which contact the first base layers 120, can be converted into first portions of the alloy layers. Furthermore, portions of the first base layers 120, which are in contact with the vertical portions of the second base layer 130, can be converted into second portions of the alloy layers. Each of these alloy layers that includes the first and second converted portions may function as a horizontal electrode 140.

A portion of each of the first base layers 120, which remains without being converted into the alloy layer, will hereinafter be referred to as a first base layer pattern 120′. In addition, a stack of the interlayer insulating layers 110 and the first base layer patterns 120′ will hereinafter be referred to as a stack pattern ST′. A pair of the horizontal electrodes 140 may extend in the first direction along both sidewalls of the first base layer pattern 120′. A width of each of the horizontal electrodes 140 in the second direction may be equal to or larger than the thickness of the second base layer 130.

Referring to FIG. 4, a variable resistance layer 150 and a conductive layer 160 may be formed over the structure resulting from the process of FIG. 3.

The variable resistance layer 150 is sandwiched between the horizontal electrode 140 and the conductive layer 160 so that a portion of the variable resistance layer 150, which overlaps with the horizontal electrode 140, can switch between different resistant states according to a voltage or a current applied from the horizontal electrode 140 and the conductive layer 160. The variable resistance layer 150 may have a single-layer structure or a multi-layer structure. The variable resistance layer 150 may include one or more of various materials that are used in RRAM, PRAM, FRAM, MRAM, and the like, for example, metal oxides such as transition metal oxides or perovskite-based materials, phase-change materials such as chalcogenide-based materials, ferroelectric materials, ferromagnetic materials, and the like.

The conductive layer 160 is used to form vertical electrodes as will be described below, and may have a single-layer structure or a multi-layer structure including one or more of various conductive materials, for example, metals such as Pt, Ir, Ru, Al, Cu, W, Ti, Ta, Co and Ni, and metal nitrides such as TiN, TiCN, TiAlN, TiON, TaN, TaCN, TaAlN, TaON, WN and MoN.

Referring to FIG. 5, the conductive layer 160 may be selectively etched to form two or more vertical electrodes 160′ which extend in the second direction and which are spaced apart from each other in the first direction.

In this implementation, when the vertical electrodes 160′ are formed, portions of the variable resistance layer 150, the second base layer 130, and the horizontal electrodes 140, which are disposed between the vertical electrodes 160′, may be etched together to form variable resistance layer patterns 150′, second base layer patterns 130′, and horizontal electrode patterns (or first electrodes) 140′, respectively. As a result, the variable resistance layer pattern 150′ and the second base layer pattern 130′ may have substantially the same planar shape as that of the vertical electrode (or a second electrode) 160′. However, implementations of the present disclosure are not limited thereto. In another implementation, at least one of the variable resistance layer 150, the second base layer 130, and the horizontal electrodes 140 may not be etched. For example, the second base layer 130 and the horizontal electrodes 140 may not be etched. This is because only an intersecting portion between the vertical electrode 160′ that extends in the second direction and the horizontal electrode pattern 140 that extends in the first direction, may function as a memory cell MC.

The processes described above can provide the semiconductor device as shown in FIG. 5.

The semiconductor device according to this implementation shown in FIG. 5 may include the stack pattern ST′, the horizontal electrode patterns 140′, the second base layer patterns 130′, the variable resistance layer patterns 150′, and the vertical electrodes 160′. The stack pattern ST′ includes the interlayer insulating layers 110 and the first base layer patterns 120′, which are alternately stacked over the substrate 100, and the stack pattern ST′ extends in the first direction. The horizontal electrode patterns 140′ are formed on sidewalls of the first base layer patterns 120′ such that inner sidewalls of the horizontal electrode patterns 140′ are in direct contact with the sidewalls of the first base layer patterns 120′, and the horizontal electrode patterns 140′ extend in the first direction. The second base layer pattern 130′ is formed on sidewalls of the interlayer insulating layers 110 such that an inner surface of the second base layer pattern 130′ are in direct contact with the sidewalls of the interlayer insulating layers 110 in a region where the second base layer pattern 130′ overlaps with the vertical electrode 160′. The variable resistance layer pattern 150′ is formed over outer sidewalls of the horizontal electrode patterns 140′ and on outer surfaces of the second base layer pattern 130′ such that portions of the horizontal electrode patterns 140′ that overlap with the vertical electrode 160′ are in direct contact with an inner surface of the variable resistance layer pattern 150′. The vertical electrode 160′ is formed on an outer surface of the variable resistance layer pattern 150′.

Herein, the horizontal electrode patterns 140′ may be formed of an alloy including not only elements included in the first base layer patterns 120′, but also elements included in the second base layer patterns 130′. The first base layer patterns 120′ and the horizontal electrode patterns 140′ serve to transfer a voltage or a current to the variable resistance layer pattern 150′, and may be electrically conductive. On the other hand, a portion of the second base layer pattern 130′ is disposed between adjacent horizontal electrode patterns 140′ in the vertical direction so as to electrically insulate the adjacent horizontal electrode patterns 140′ from each other, and the second layer pattern 130′ may be dielectric.

The outer sidewalls of the horizontal electrode patterns 140′ may be substantially coplanar with the outer surface of the second base layer pattern 130′ in the portions of the horizontal electrode patterns 140′ that overlap with the vertical electrode 160′. On the other hand, the inner sidewalls of the horizontal electrode patterns 140′ may be substantially coplanar with the inner surface of the second base layer pattern 130′, or may protrude more towards the first base layer patterns 120′ than the inner surface of the second base layer pattern 130′. Thus, a width of each of the horizontal electrode patterns 140′ in the second direction may be substantially equal to or larger than the thickness of the second base layer pattern 130′. According to an implementation, the second base layer pattern 130′ may have a shape extending in the second direction, so that it can also be located on a top surface of an uppermost interlayer insulating layer 110 of each stack pattern ST′ and on a top surface of the substrate 100 between two stack patterns ST′ adjacent to each other in the second direction.

With respect to a single stack pattern ST′, the variable resistance layer pattern 150′ and the vertical electrode 160′ may extend in the vertical direction (or a third direction), so that they can be located on sidewalls of both the second base layer pattern 130′ and the horizontal electrode patterns 140′ that are in contact with the single stack pattern ST′. Furthermore, according to an implementation, with respect to stack patterns ST′ adjacent to each other in the second direction, the variable resistance layer pattern 150′ and the vertical electrode 160′ may have a shape extending in the second direction, so that it can also be located over the uppermost interlayer insulating layers 110 of the adjacent stack patterns ST′ and over portions of the substrate 100 between the adjacent stack patterns ST′.

In this semiconductor device, a single horizontal electrode pattern 140′, a portion of the vertical electrode 160′ that overlaps with the horizontal electrode pattern 140′, and a portion of the variable resistance layer pattern 150′ interposed therebetween may form a memory cell MC.

In the memory cell MC, a conductive path can be formed in the portion of the variable resistance layer pattern 150′ in a direction substantially parallel to the second direction or removed from the portion of the variable resistance layer pattern 150′ according to a voltage or a current applied through the horizontal electrode pattern 140′ and the vertical electrode 160′. Thus, the memory cell MC can switch between a low-resistance state and a high-resistance state. The horizontal electrode pattern 140′ can be in direct contact with a wiring (not shown) to receive a voltage or a current. Alternatively, the first base layer pattern 120′ can be in direct contact with a wiring (not shown) to receive a current or a voltage, and thus the horizontal electrode pattern 140′ can receive the voltage or the current through the first base layer pattern 120′.

According to the semiconductor device and the fabrication method thereof described above, selection of a material suitable for a horizontal electrode can be facilitated because an etching process is not used in the formation of the horizontal electrode. For example, a TiAlN alloy may be used as the horizontal electrode.

As a result, the process of fabricating the semiconductor device can be easily performed using an electrode material that improves the characteristics of the variable resistance element.

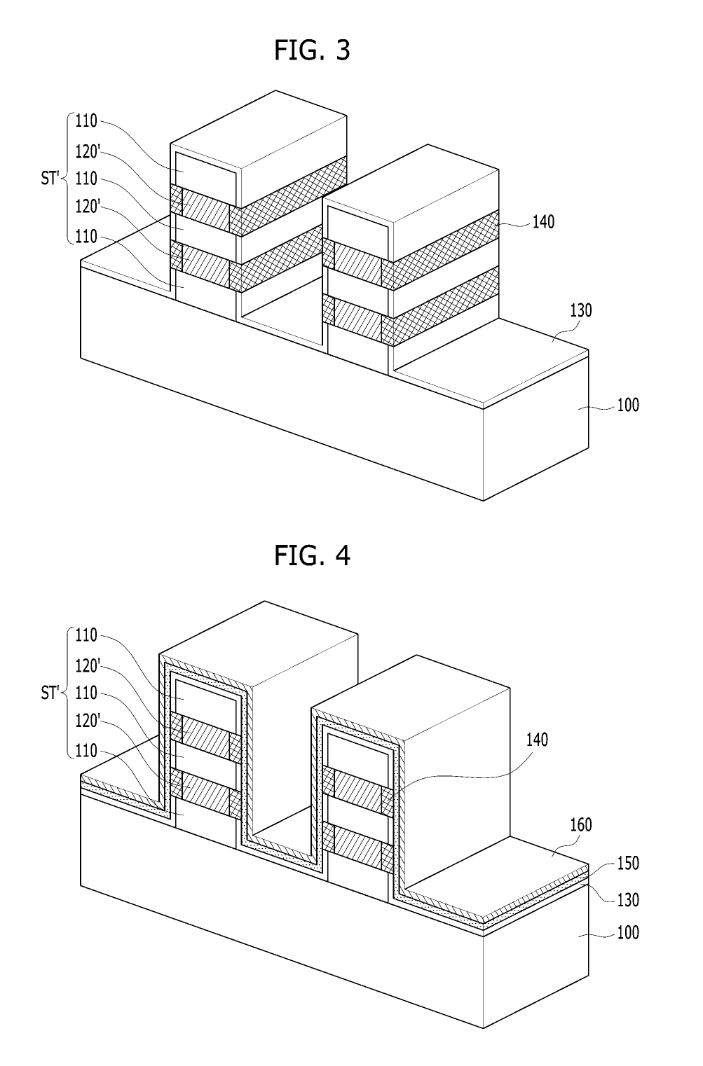

Meanwhile, the variable resistance layer pattern 150′ in the semiconductor device may have a multi-layer structure consisting of a combination of two or more layers, which exhibits variable resistance characteristics. Each of the two or more layers may extend in a third direction (e.g., the vertical direction with respect to the orientation of FIG. 5) perpendicular to the top surface of the substrate 100. Hereinafter, an implementation of the disclosed technology will be described by way of example with reference to FIG. 6.

FIG. 6 illustrates a semiconductor device according to an implementation of the present disclosure, and is an enlarged view of a portion corresponding to the memory cell MC shown in FIG. 5. The detailed description of parts substantially identical to those shown in FIG. 5 will be omitted.

Referring to FIG. 6, a variable resistance layer pattern 150′ in the semiconductor device according to this implementation may have a multi-layer structure consisting of a first pattern 150A′ and a second pattern 150B′, and can exhibit variable resistance characteristics by a combination of the first pattern 150A′ and the second pattern 150B′.

For example, any one of the first pattern 150A′ and the second pattern 150B′ may be formed of an oxygen-rich metal oxide, and the other one may be formed of an oxygen-deficient metal oxide. Herein, the oxygen-rich metal oxide may be a material that satisfies the stoichiometric ratio, such as TiO₂ or Ta₂O₅, and the oxygen-deficient metal oxide may be a material having an oxygen content lower than the stoichiometric ratio, such as TiOx (wherein x<2) or TaOy (wherein y<2.5). The resistance state of this variable resistance layer pattern 150′ can be switched between a high-resistance state and a low-resistance state, depending on whether oxygen vacancies in the oxygen-deficient metal oxide are supplied to the oxygen-rich metal oxide and thus whether a filamentary current path is formed by the supplied oxygen vacancies in the oxygen-rich metal oxide.

However, implementations of the disclosed technology are not limited thereto, and the variable resistance layer pattern 150′ may include any of various materials and have any of various stack structures, as long as the variable resistance layer pattern 150′ is interposed between the horizontal electrode pattern 140′ and the vertical electrode 160′ and switches between different resistance states.

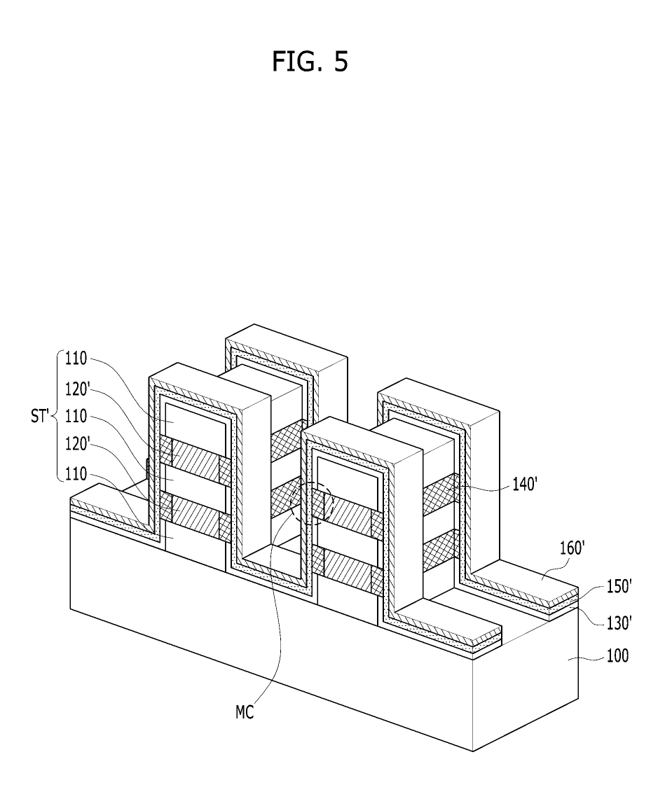

Meanwhile, the memory cell MC in the semiconductor device described above may further include a selection element layer that is interposed between the horizontal electrode pattern 140′ and the vertical electrode 160′ while being connected to the variable resistance layer pattern 150′. In this case, the selection element layer may extend in a direction (e.g., the vertical direction of FIG. 5) that is parallel to the variable resistance layer pattern 150′ and perpendicular to the top surface of the substrate 100. Hereinafter, an implementation of the disclosed technology including a selection element layer will be described with reference to FIG. 7.

FIG. 7 illustrates a semiconductor device according to an implementation of the present invention, and particularly, is an enlarged view of a portion corresponding to the memory cell MC shown in FIG. 5. The detailed description of parts substantially identical to those shown in FIG. 5 will be omitted.

Referring to FIG. 7, the semiconductor device according to the present invention may further include a selection element layer 180 interposed between the variable resistance layer pattern 150′ and the vertical electrode 160′.

The selection element layer 180 substantially prevents a current from flowing therethrough when a magnitude of an applied voltage or current is lower than a certain threshold value. The selection element layer 180 can cause a current to flow therethrough such that a magnitude of the flowing current gradually increases substantially in proportion to the magnitude of the applied voltage or current, when the magnitude of the applied voltage or current exceeds the threshold value.

The selection element layer 180 may be a diode, an MIT (metal insulator transition) element such as NbO₂ or TiO₂, an MIEC (mixed ion-electron conducting) element such as ZrO₂ (Y₂O₃) or Bi₂O₃—BaO, (La₂O₃)x(CeO₂)1-x, an OTS (ovonic threshold switching) element including a chalcogenide-based material such as Ge₂Sb₂Te₅, As₂Te₃, Asₑ or As₂Se₃, or a tunneling dielectric layer including various dielectric materials and having a small thickness.

This selection element layer 180 can substantially prevent current leakage from occurring between the memory cells MC. In an implementation, the selection element layer 180 may be interposed between the variable resistance layer pattern 150′ and the horizontal electrode pattern 140′.

According to the electronic devices and the fabrication method thereof described above, the process of fabricating the electronic device can be easily performed, and the characteristics of the variable resistance element can be improved.

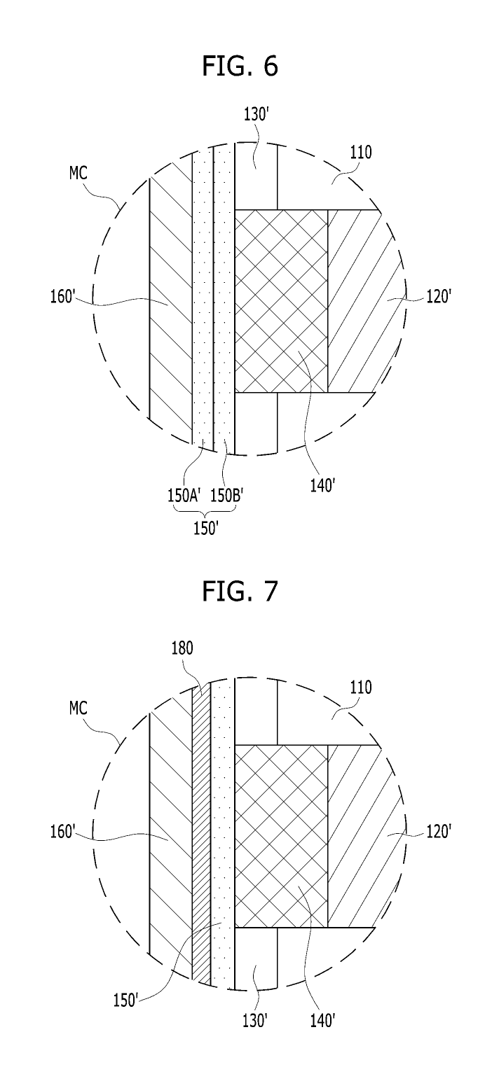

The above and other memory circuits or semiconductor devices based on the disclosed technology can be used in a range of devices or systems. FIGS. 8-12 provide some examples of devices or systems that can implement the memory circuits disclosed herein.

FIG. 8 is an example of configuration diagram of a microprocessor implementing memory circuitry based on the disclosed technology.

Referring to FIG. 8, a microprocessor 1000 may perform tasks for controlling and tuning a series of processes of receiving data from various external devices, processing the data, and outputting processing results to external devices. The microprocessor 1000 may include a memory unit 1010, an operation unit 1020, a control unit 1030, and so on. The microprocessor 1000 may be various data processing units such as a central processing unit (CPU), a graphic processing unit (GPU), a digital signal processor (DSP) and an application processor (AP).

The memory unit 1010 is a part which stores data in the microprocessor 1000, as a processor register, register or the like. The memory unit 1010 may include a data register, an address register, a floating point register and so on. Besides, the memory unit 1010 may include various registers. The memory unit 1010 may perform the function of temporarily storing data for which operations are to be performed by the operation unit 1020, result data of performing the operations and addresses where data for performing of the operations are stored.

The memory unit 1010 may include one or more of the above-described semiconductor devices in accordance with the implementations. For example, the memory unit 1010 may include interlayer insulating layers and conductive first base layer patterns that are alternatively stacked over a substrate; a dielectric second base layer pattern that is in contact with sidewalls of the interlayer insulating layers; first electrodes that are in contact with sidewalls of the first base layer patterns; a second electrode disposed over outer sidewalls of the first electrodes; and a variable resistance layer pattern interposed between the first electrodes and the second electrode, wherein each of the first electrodes comprises an alloy that includes first and second elements, the first element being included in the first base layer patterns, and the second element being included in the second base layer pattern. Through this, fabricating processes of the memory unit 1010 may be easy, and characteristics of memory cells of the memory unit 1010 may be improved. As a consequence, operating characteristics of the microprocessor 1000 may be improved.

The operation unit 1020 may perform four arithmetical operations or logical operations according to results that the control unit 1030 decodes commands. The operation unit 1020 may include at least one arithmetic logic unit (ALU) and so on.

The control unit 1030 may receive signals from the memory unit 1010, the operation unit 1020 and an external device of the microprocessor 1000, perform extraction, decoding of commands, and controlling input and output of signals of the microprocessor 1000, and execute processing represented by programs.

The microprocessor 1000 according to the present implementation may additionally include a cache memory unit 1040 which can temporarily store data to be inputted from an external device other than the memory unit 1010 or to be outputted to an external device. In this case, the cache memory unit 1040 may exchange data with the memory unit 1010, the operation unit 1020 and the control unit 1030 through a bus interface 1050.

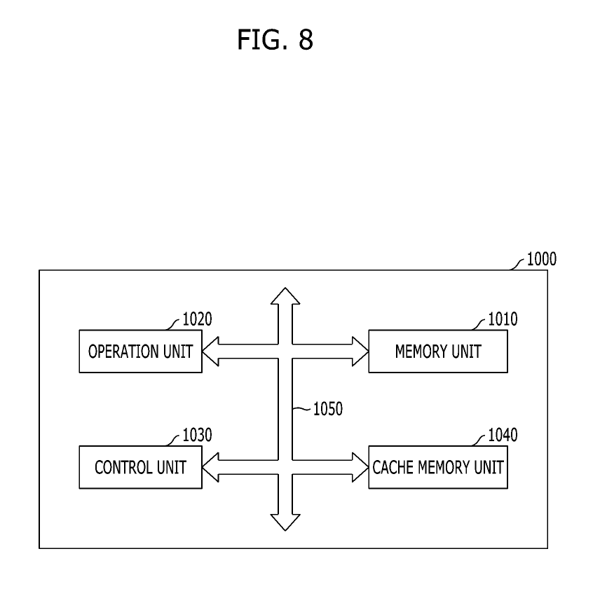

FIG. 9 is an example of configuration diagram of a processor implementing memory circuitry based on the disclosed technology.

Referring to FIG. 9, a processor 1100 may improve performance and realize multi-functionality by including various functions other than those of a microprocessor which performs tasks for controlling and tuning a series of processes of receiving data from various external devices, processing the data, and outputting processing results to external devices. The processor 1100 may include a core unit 1110 which serves as the microprocessor, a cache memory unit 1120 which serves to storing data temporarily, and a bus interface 1130 for transferring data between internal and external devices. The processor 1100 may include various system-on-chips (SoCs) such as a multi-core processor, a graphic processing unit (GPU) and an application processor (AP).

The core unit 1110 of the present implementation is a part which performs arithmetic logic operations for data inputted from an external device, and may include a memory unit 1111, an operation unit 1112 and a control unit 1113.

The memory unit 1111 is a part which stores data in the processor 1100, as a processor register, a register or the like. The memory unit 1111 may include a data register, an address register, a floating point register and so on. Besides, the memory unit 1111 may include various registers. The memory unit 1111 may perform the function of temporarily storing data for which operations are to be performed by the operation unit 1112, result data of performing the operations and addresses where data for performing of the operations are stored. The operation unit 1112 is a part which performs operations in the processor 1100. The operation unit 1112 may perform four arithmetical operations, logical operations, according to results that the control unit 1113 decodes commands, or the like. The operation unit 1112 may include at least one arithmetic logic unit (ALU) and so on. The control unit 1113 may receive signals from the memory unit 1111, the operation unit 1112 and an external device of the processor 1100, perform extraction, decoding of commands, controlling input and output of signals of processor 1100, and execute processing represented by programs.

The cache memory unit 1120 is a part which temporarily stores data to compensate for a difference in data processing speed between the core unit 1110 operating at a high speed and an external device operating at a low speed. The cache memory unit 1120 may include a primary storage section 1121, a secondary storage section 1122 and a tertiary storage section 1123. In general, the cache memory unit 1120 includes the primary and secondary storage sections 1121 and 1122, and may include the tertiary storage section 1123 in the case where high storage capacity is required. As the occasion demands, the cache memory unit 1120 may include an increased number of storage sections. That is to say, the number of storage sections which are included in the cache memory unit 1120 may be changed according to a design. The speeds at which the primary, secondary and tertiary storage sections 1121, 1122 and 1123 store and discriminate data may be the same or different. In the case where the speeds of the respective storage sections 1121, 1122 and 1123 are different, the speed of the primary storage section 1121 may be largest. At least one storage section of the primary storage section 1121, the secondary storage section 1122 and the tertiary storage section 1123 of the cache memory unit 1120 may include one or more of the above-described semiconductor devices in accordance with the implementations. For example, the cache memory unit 1120 may include interlayer insulating layers and conductive first base layer patterns that are alternatively stacked over a substrate; a dielectric second base layer pattern that is in contact with sidewalls of the interlayer insulating layers; first electrodes that are in contact with sidewalls of the first base layer patterns; a second electrode disposed over outer sidewalls of the first electrodes; and a variable resistance layer pattern interposed between the first electrodes and the second electrode, wherein each of the first electrodes comprises an alloy that includes first and second elements, the first element being included in the first base layer patterns, and the second element being included in the second base layer pattern. Through this, fabricating processes of the cache memory unit 1120 may be easy, and characteristics of memory cells of the cache memory unit 1120 may be improved. As a consequence, operating characteristics of the processor 1100 may be improved.

Although it was shown in FIG. 9 that all the primary, secondary and tertiary storage sections 1121, 1122 and 1123 are configured inside the cache memory unit 1120, it is to be noted that all the primary, secondary and tertiary storage sections 1121, 1122 and 1123 of the cache memory unit 1120 may be configured outside the core unit 1110 and may compensate for a difference in data processing speed between the core unit 1110 and the external device. Meanwhile, it is to be noted that the primary storage section 1121 of the cache memory unit 1120 may be disposed inside the core unit 1110 and the secondary storage section 1122 and the tertiary storage section 1123 may be configured outside the core unit 1110 to strengthen the function of compensating for a difference in data processing speed. In another implementation, the primary and secondary storage sections 1121, 1122 may be disposed inside the core units 1110 and tertiary storage sections 1123 may be disposed outside core units 1110.

The bus interface 1130 is a part which connects the core unit 1110, the cache memory unit 1120 and external device and allows data to be efficiently transmitted.

The processor 1100 according to the present implementation may include a plurality of core units 1110, and the plurality of core units 1110 may share the cache memory unit 1120. The plurality of core units 1110 and the cache memory unit 1120 may be directly connected or be connected through the bus interface 1130. The plurality of core units 1110 may be configured in the same way as the above-described configuration of the core unit 1110. In the case where the processor 1100 includes the plurality of core unit 1110, the primary storage section 1121 of the cache memory unit 1120 may be configured in each core unit 1110 in correspondence to the number of the plurality of core units 1110, and the secondary storage section 1122 and the tertiary storage section 1123 may be configured outside the plurality of core units 1110 in such a way as to be shared through the bus interface 1130. The processing speed of the primary storage section 1121 may be larger than the processing speeds of the secondary and tertiary storage section 1122 and 1123. In another implementation, the primary storage section 1121 and the secondary storage section 1122 may be configured in each core unit 1110 in correspondence to the number of the plurality of core units 1110, and the tertiary storage section 1123 may be configured outside the plurality of core units 1110 in such a way as to be shared through the bus interface 1130.

The processor 1100 according to the present implementation may further include an embedded memory unit 1140 which stores data, a communication module unit 1150 which can transmit and receive data to and from an external device in a wired or wireless manner, a memory control unit 1160 which drives an external memory device, and a media processing unit 1170 which processes the data processed in the processor 1100 or the data inputted from an external input device and outputs the processed data to an external interface device and so on. Besides, the processor 1100 may include a plurality of various modules and devices. In this case, the plurality of modules which are added may exchange data with the core units 1110 and the cache memory unit 1120 and with one another, through the bus interface 1130.

The embedded memory unit 1140 may include not only a volatile memory but also a nonvolatile memory. The volatile memory may include a DRAM (dynamic random access memory), a mobile DRAM, an SRAM (static random access memory), and a memory with similar functions to above mentioned memories, and so on. The nonvolatile memory may include a ROM (read only memory), a NOR flash memory, a NAND flash memory, a phase change random access memory (PRAM), a resistive random access memory (RRAM), a spin transfer torque random access memory (STTRAM), a magnetic random access memory (MRAM), a memory with similar functions.

The communication module unit 1150 may include a module capable of being connected with a wired network, a module capable of being connected with a wireless network and both of them. The wired network module may include a local area network (LAN), a universal serial bus (USB), an Ethernet, power line communication (PLC) such as various devices which send and receive data through transmit lines, and so on. The wireless network module may include Infrared Data Association (IrDA), code division multiple access (CDMA), time division multiple access (TDMA), frequency division multiple access (FDMA), a wireless LAN, Zigbee, a ubiquitous sensor network (USN), Bluetooth, radio frequency identification (RFID), long term evolution (LTE), near field communication (NFC), a wireless broadband Internet (Wibro), high speed downlink packet access (HSDPA), wideband CDMA (WCDMA), ultra wideband (UWB) such as various devices which send and receive data without transmit lines, and so on.

The memory control unit 1160 is to administrate and process data transmitted between the processor 1100 and an external storage device operating according to a different communication standard. The memory control unit 1160 may include various memory controllers, for example, devices which may control IDE (Integrated Device Electronics), SATA (Serial Advanced Technology Attachment), SCSI (Small Computer System Interface), RAID (Redundant Array of Independent Disks), an SSD (solid state disk), eSATA (External SATA), PCMCIA (Personal Computer Memory Card International Association), a USB (universal serial bus), a secure digital (SD) card, a mini secure digital (mSD) card, a micro secure digital (micro SD) card, a secure digital high capacity (SDHC) card, a memory stick card, a smart media (SM) card, a multimedia card (MMC), an embedded MMC (eMMC), a compact flash (CF) card, and so on.

The media processing unit 1170 may process the data processed in the processor 1100 or the data inputted in the forms of image, voice and others from the external input device and output the data to the external interface device. The media processing unit 1170 may include a graphic processing unit (GPU), a digital signal processor (DSP), a high definition audio device (HD audio), a high definition multimedia interface (HDMI) controller, and so on.

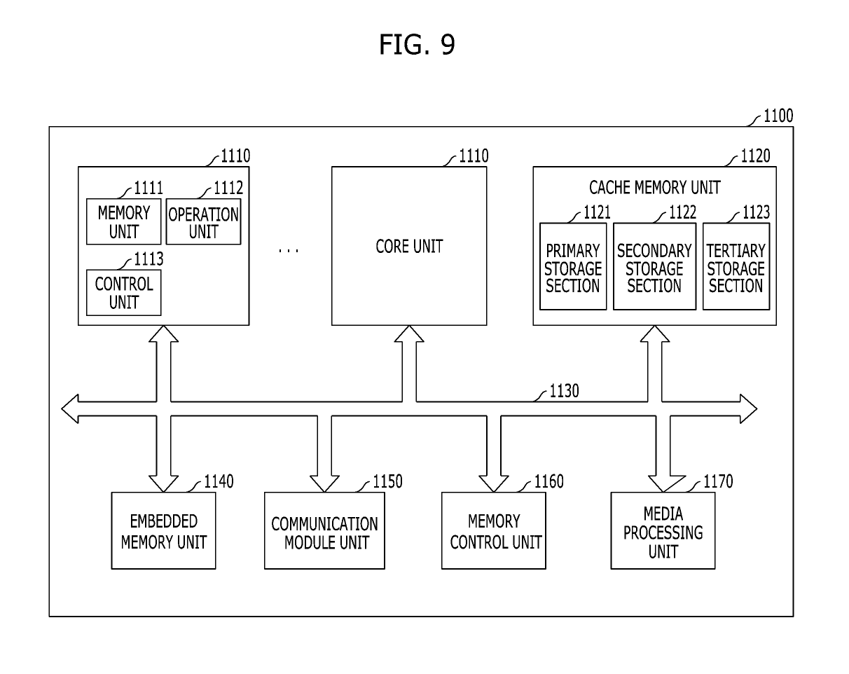

FIG. 10 is an example of configuration diagram of a system implementing memory circuitry based on the disclosed technology.

Referring to FIG. 10, a system 1200 as an apparatus for processing data may perform input, processing, output, communication, storage, etc. to conduct a series of manipulations for data. The system 1200 may include a processor 1210, a main memory device 1220, an auxiliary memory device 1230, an interface device 1240, and so on. The system 1200 of the present implementation may be various electronic systems which operate using processors, such as a computer, a server, a PDA (personal digital assistant), a portable computer, a web tablet, a wireless phone, a mobile phone, a smart phone, a digital music player, a PMP (portable multimedia player), a camera, a global positioning system (GPS), a video camera, a voice recorder, a telematics, an audio visual (AV) system, a smart television, and so on.

The processor 1210 may decode inputted commands and processes operation, comparison, etc. for the data stored in the system 1200, and controls these operations. The processor 1210 may include a microprocessor unit (MPU), a central processing unit (CPU), a single/multi-core processor, a graphic processing unit (GPU), an application processor (AP), a digital signal processor (DSP), and so on.

The main memory device 1220 is a storage which can temporarily store, call and execute program codes or data from the auxiliary memory device 1230 when programs are executed and can conserve memorized contents even when power supply is cut off. The main memory device 1220 may include one or more of the above-described semiconductor devices in accordance with the implementations. For example, the main memory device 1220 may include interlayer insulating layers and conductive first base layer patterns that are alternatively stacked over a substrate; a dielectric second base layer pattern that is in contact with sidewalls of the interlayer insulating layers; first electrodes that are in contact with sidewalls of the first base layer patterns; a second electrode disposed over outer sidewalls of the first electrodes; and a variable resistance layer pattern interposed between the first electrodes and the second electrode, wherein each of the first electrodes comprises an alloy that includes first and second elements, the first element being included in the first base layer patterns, and the second element being included in the second base layer pattern. Through this, fabricating processes of the main memory device 1220 may be easy, and characteristics of memory cells of the main memory device 1220 may be improved. As a consequence, operating characteristics of the system 1200 may be improved.

Also, the main memory device 1220 may further include a static random access memory (SRAM), a dynamic random access memory (DRAM), and so on, of a volatile memory type in which all contents are erased when power supply is cut off. Unlike this, the main memory device 1220 may not include the semiconductor devices according to the implementations, but may include a static random access memory (SRAM), a dynamic random access memory (DRAM), and so on, of a volatile memory type in which all contents are erased when power supply is cut off.

The auxiliary memory device 1230 is a memory device for storing program codes or data. While the speed of the auxiliary memory device 1230 is slower than the main memory device 1220, the auxiliary memory device 1230 can store a larger amount of data. The auxiliary memory device 1230 may include one or more of the above-described semiconductor devices in accordance with the implementations. For example, the auxiliary memory device 1230 may include interlayer insulating layers and conductive first base layer patterns that are alternatively stacked over a substrate; a dielectric second base layer pattern that is in contact with sidewalls of the interlayer insulating layers; first electrodes that are in contact with sidewalls of the first base layer patterns; a second electrode disposed over outer sidewalls of the first electrodes; and a variable resistance layer pattern interposed between the first electrodes and the second electrode, wherein each of the first electrodes comprises an alloy that includes first and second elements, the first element being included in the first base layer patterns, and the second element being included in the second base layer pattern. Through this, fabricating processes of the auxiliary memory device 1230 may be easy, and characteristics of memory cells of the auxiliary memory device 1230 may be improved. As a consequence, operating characteristics of the system 1200 may be improved.

Also, the auxiliary memory device 1230 may further include a data storage system (see the reference numeral 1300 of FIG. 10) such as a magnetic tape using magnetism, a magnetic disk, a laser disk using optics, a magneto-optical disc using both magnetism and optics, a solid state disk (SSD), a USB memory (universal serial bus memory), a secure digital (SD) card, a mini secure digital (mSD) card, a micro secure digital (micro SD) card, a secure digital high capacity (SDHC) card, a memory stick card, a smart media (SM) card, a multimedia card (MMC), an embedded MMC (eMMC), a compact flash (CF) card, and so on. Unlike this, the auxiliary memory device 1230 may not include the semiconductor devices according to the implementations, but may include data storage systems (see the reference numeral 1300 of FIG. 10) such as a magnetic tape using magnetism, a magnetic disk, a laser disk using optics, a magneto-optical disc using both magnetism and optics, a solid state disk (SSD), a USB memory (universal serial bus memory), a secure digital (SD) card, a mini secure digital (mSD) card, a micro secure digital (micro SD) card, a secure digital high capacity (SDHC) card, a memory stick card, a smart media (SM) card, a multimedia card (MMC), an embedded MMC (eMMC), a compact flash (CF) card, and so on.

The interface device 1240 may be to perform exchange of commands and data between the system 1200 of the present implementation and an external device. The interface device 1240 may be a keypad, a keyboard, a mouse, a speaker, a mike, a display, various human interface devices (HIDs), a communication device, and so on. The communication device may include a module capable of being connected with a wired network, a module capable of being connected with a wireless network and both of them. The wired network module may include a local area network (LAN), a universal serial bus (USB), an Ethernet, power line communication (PLC), such as various devices which send and receive data through transmit lines, and so on. The wireless network module may include Infrared Data Association (IrDA), code division multiple access (CDMA), time division multiple access (TDMA), frequency division multiple access (FDMA), a wireless LAN, Zigbee, a ubiquitous sensor network (USN), Bluetooth, radio frequency identification (RFID), long term evolution (LTE), near field communication (NFC), a wireless broadband Internet (Wibro), high speed downlink packet access (HSDPA), wideband CDMA (WCDMA), ultra wideband (UWB), such as various devices which send and receive data without transmit lines, and so on.

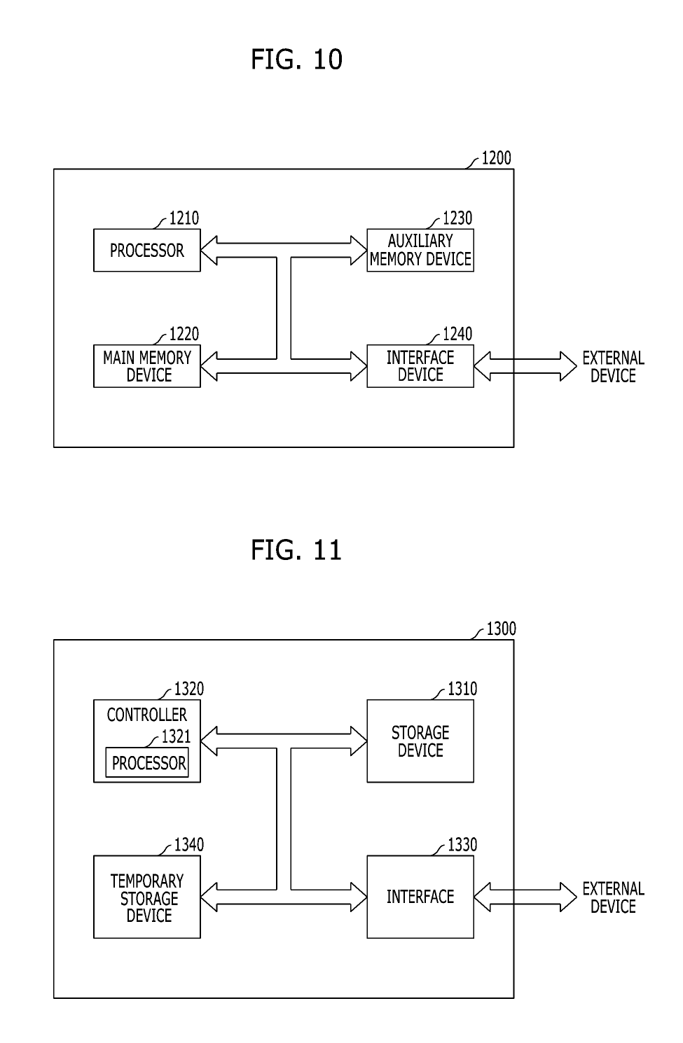

FIG. 11 is an example of configuration diagram of a data storage system implementing memory circuitry based on the disclosed technology.

Referring to FIG. 11, a data storage system 1300 may include a storage device 1310 which has a nonvolatile characteristic as a component for storing data, a controller 1320 which controls the storage device 1310, an interface 1330 for connection with an external device, and a temporary storage device 1340 for storing data temporarily. The data storage system 1300 may be a disk type such as a hard disk drive (HDD), a compact disc read only memory (CDROM), a digital versatile disc (DVD), a solid state disk (SSD), and so on, and a card type such as a USB memory (universal serial bus memory), a secure digital (SD) card, a mini secure digital (mSD) card, a micro secure digital (micro SD) card, a secure digital high capacity (SDHC) card, a memory stick card, a smart media (SM) card, a multimedia card (MMC), an embedded MMC (eMMC), a compact flash (CF) card, and so on.

The storage device 1310 may include a nonvolatile memory which stores data semi-permanently. The nonvolatile memory may include a ROM (read only memory), a NOR flash memory, a NAND flash memory, a phase change random access memory (PRAM), a resistive random access memory (RRAM), a magnetic random access memory (MRAM), and so on.

The controller 1320 may control exchange of data between the storage device 1310 and the interface 1330. To this end, the controller 1320 may include a processor 1321 for performing an operation for, processing commands inputted through the interface 1330 from an outside of the data storage system 1300 and so on.

The interface 1330 is to perform exchange of commands and data between the data storage system 1300 and the external device. In the case where the data storage system 1300 is a card type, the interface 1330 may be compatible with interfaces which are used in devices, such as a USB memory (universal serial bus memory), a secure digital (SD) card, a mini secure digital (mSD) card, a micro secure digital (micro SD) card, a secure digital high capacity (SDHC) card, a memory stick card, a smart media (SM) card, a multimedia card (MMC), an embedded MMC (eMMC), a compact flash (CF) card, and so on, or be compatible with interfaces which are used in devices similar to the above mentioned devices. In the case where the data storage system 1300 is a disk type, the interface 1330 may be compatible with interfaces, such as IDE (Integrated Device Electronics), SATA (Serial Advanced Technology Attachment), SCSI (Small Computer System Interface), eSATA (External SATA), PCMCIA (Personal Computer Memory Card International Association), a USB (universal serial bus), and so on, or be compatible with the interfaces which are similar to the above mentioned interfaces. The interface 1330 may be compatible with one or more interfaces having a different type from each other.

The temporary storage device 1340 can store data temporarily for efficiently transferring data between the interface 1330 and the storage device 1310 according to diversifications and high performance of an interface with an external device, a controller and a system. The temporary storage device 1340 for temporarily storing data may include one or more of the above-described semiconductor devices in accordance with the implementations. The temporary storage device 1340 may include interlayer insulating layers and conductive first base layer patterns that are alternatively stacked over a substrate; a dielectric second base layer pattern that is in contact with sidewalls of the interlayer insulating layers; first electrodes that are in contact with sidewalls of the first base layer patterns; a second electrode disposed over outer sidewalls of the first electrodes; and a variable resistance layer pattern interposed between the first electrodes and the second electrode, wherein each of the first electrodes comprises an alloy that includes first and second elements, the first element being included in the first base layer patterns, and the second element being included in the second base layer pattern. Through this, fabricating processes of the temporary storage device 1340 may be easy, and characteristics of memory cells of the temporary storage device 1340 may be improved. As a consequence, operating characteristics and data storage characteristics of the data storage system 1300 may be improved.

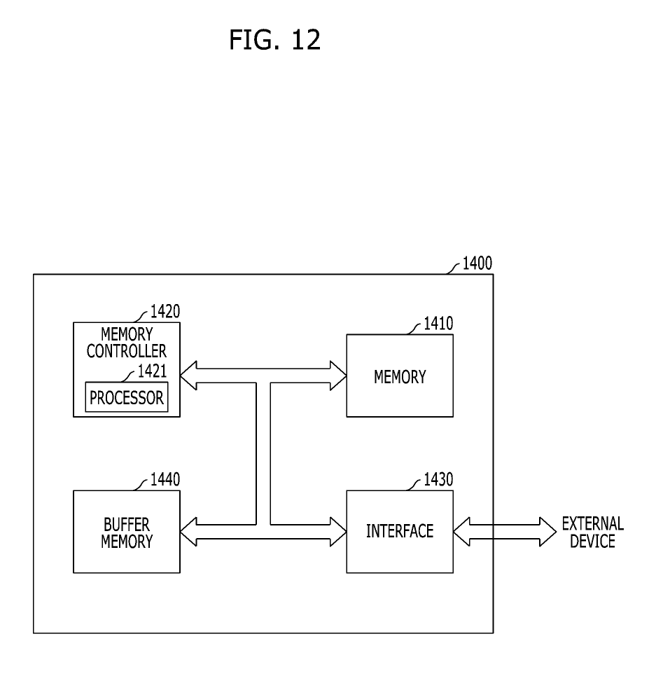

FIG. 12 is an example of configuration diagram of a memory system implementing memory circuitry based on the disclosed technology.

Referring to FIG. 12, a memory system 1400 may include a memory 1410 which has a nonvolatile characteristic as a component for storing data, a memory controller 1420 which controls the memory 1410, an interface 1430 for connection with an external device, and so on. The memory system 1400 may be a card type such as a solid state disk (SSD), a USB memory (universal serial bus memory), a secure digital (SD) card, a mini secure digital (mSD) card, a micro secure digital (micro SD) card, a secure digital high capacity (SDHC) card, a memory stick card, a smart media (SM) card, a multimedia card (MMC), an embedded MMC (eMMC), a compact flash (CF) card, and so on.

The memory 1410 for storing data may include one or more of the above-described semiconductor devices in accordance with the implementations. For example, the memory 1410 may include interlayer insulating layers and conductive first base layer patterns that are alternatively stacked over a substrate; a dielectric second base layer pattern that is in contact with sidewalls of the interlayer insulating layers; first electrodes that are in contact with sidewalls of the first base layer patterns; a second electrode disposed over outer sidewalls of the first electrodes; and a variable resistance layer pattern interposed between the first electrodes and the second electrode, wherein each of the first electrodes comprises an alloy that includes first and second elements, the first element being included in the first base layer patterns, and the second element being included in the second base layer pattern. Through this, fabricating processes of the memory 1410 may be easy, and characteristics of memory cells of the memory 1410 may be improved. As a consequence, operating characteristics and memory characteristics of the memory system 1400 may be improved.

Also, the memory 1410 according to the present implementation may further include a ROM (read only memory), a NOR flash memory, a NAND flash memory, a phase change random access memory (PRAM), a resistive random access memory (RRAM), a magnetic random access memory (MRAM), and so on, which have a nonvolatile characteristic.

The memory controller 1420 may control exchange of data between the memory 1410 and the interface 1430. To this end, the memory controller 1420 may include a processor 1421 for performing an operation for and processing commands inputted through the interface 1430 from an outside of the memory system 1400.

The interface 1430 is to perform exchange of commands and data between the memory system 1400 and the external device. The interface 1430 may be compatible with interfaces which are used in devices, such as a USB memory (universal serial bus memory), a secure digital (SD) card, a mini secure digital (mSD) card, a micro secure digital (micro SD) card, a secure digital high capacity (SDHC) card, a memory stick card, a smart media (SM) card, a multimedia card (MMC), an embedded MMC (eMMC), a compact flash (CF) card, and so on, or be compatible with interfaces which are used in devices similar to the above mentioned devices. The interface 1430 may be compatible with one or more interfaces having a different type from each other.

The memory system 1400 according to the present implementation may further include a buffer memory 1440 for efficiently transferring data between the interface 1430 and the memory 1410 according to diversification and high performance of an interface with an external device, a memory controller and a memory system. For example, the buffer memory 1440 for temporarily storing data may include one or more of the above-described semiconductor devices in accordance with the implementations. The buffer memory 1440 may include interlayer insulating layers and conductive first base layer patterns that are alternatively stacked over a substrate; a dielectric second base layer pattern that is in contact with sidewalls of the interlayer insulating layers; first electrodes that are in contact with sidewalls of the first base layer patterns; a second electrode disposed over outer sidewalls of the first electrodes; and a variable resistance layer pattern interposed between the first electrodes and the second electrode, wherein each of the first electrodes comprises an alloy that includes first and second elements, the first element being included in the first base layer patterns, and the second element being included in the second base layer pattern. Through this, fabricating processes of the buffer memory 1440 may be easy, and characteristics of memory cells of the buffer memory 1440 1010 may be improved. As a consequence, operating characteristics and memory characteristics of the memory system 1400 may be improved.

Moreover, the buffer memory 1440 according to the present implementation may further include an SRAM (static random access memory), a DRAM (dynamic random access memory), and so on, which have a volatile characteristic, and a phase change random access memory (PRAM), a resistive random access memory (RRAM), a spin transfer torque random access memory (STTRAM), a magnetic random access memory (MRAM), and so on, which have a nonvolatile characteristic. Unlike this, the buffer memory 1440 may not include the semiconductor devices according to the implementations, but may include an SRAM (static random access memory), a DRAM (dynamic random access memory), and so on, which have a volatile characteristic, and a phase change random access memory (PRAM), a resistive random access memory (RRAM), a spin transfer torque random access memory (STTRAM), a magnetic random access memory (MRAM), and so on, which have a nonvolatile characteristic.

Features in the above examples of electronic devices or systems in FIGS. 8-12 based on the memory devices disclosed in this document may be implemented in various devices, systems or applications. Some examples include mobile phones or other portable communication devices, tablet computers, notebook or laptop computers, game machines, smart TV sets, TV set top boxes, multimedia servers, digital cameras with or without wireless communication functions, wrist watches or other wearable devices with wireless communication capabilities.

While this patent document contains many specifics, these should not be construed as limitations on the scope of any invention or of what may be claimed, but rather as descriptions of features that may be specific to particular embodiments of particular inventions. Certain features that are described in this patent document in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. Moreover, the separation of various system components in the embodiments described in this patent document should not be understood as requiring such separation in all embodiments.

Only a few implementations and examples are described. Other implementations, enhancements and variations can be made based on what is described and illustrated in this patent document.

What is claimed is:

1. An electronic device comprising a semiconductor memory, wherein the semiconductor memory comprises:
interlayer insulating layers and conductive first base layer patterns that are alternatively stacked over a substrate;
a dielectric second base layer pattern that is in contact with sidewalls of the interlayer insulating layers;
first electrodes that are in contact with sidewalls of the first base layer patterns;
a second electrode disposed over outer sidewalls of the first electrodes; and
a variable resistance layer pattern interposed between the first electrodes and the second electrode,
wherein each of the first electrodes comprises an alloy that includes first and second elements, the first element being included in the first base layer patterns, and the second element being included in the second base layer pattern.

2. The electronic device of claim 1, wherein the first base layer patterns include TiN, the second base layer pattern includes AlN, and the first electrodes comprise TiAlN.

3. The electronic device of claim 1, wherein a width of each of the interlayer insulating layers in a direction is equal to or greater than a width of each of the first base layer patterns in the direction, the direction being substantially parallel to a top surface of the substrate.

4. The electronic device of claim 1, wherein a width of each of the first electrodes in a direction is equal to or greater than a thickness of the second base layer pattern in the direction, the direction being substantially parallel to a top surface of the substrate.

5. The electronic device of claim 1, wherein an outer sidewall of each of the first electrodes is substantially coplanar with an outer sidewall of the second base layer pattern.

6. The electronic device of claim 5, wherein an inner sidewall of each of the first electrodes protrudes more towards a corresponding one of the first base layer patterns than an inner sidewall of the second base layer pattern.

7. The electronic device of claim 1, wherein the interlayer insulating layers, the first base layer patterns, and the first electrodes extend in a first direction, and the second electrode extends in a second direction such that the second electrode overlaps with the first electrodes and the second base layer pattern, the first direction being parallel to a top surface of the substrate, the second direction being perpendicular to the top surface of the substrate.

8. The electronic device of claim 7, wherein the second electrode extends in a third direction that intersects with the first direction and that is perpendicular to the second direction.

9. The electronic device of claim 8, wherein the variable resistance layer pattern overlaps with the second electrode.

10. The electronic device of claim 7, wherein the variable resistance layer pattern overlaps with the second electrode.

11. The electronic device of claim 1, wherein a resistance of a portion of the variable resistance layer pattern is switched by formation or removal of a conductive path in the portion of the variable resistance layer pattern according to a voltage or a current applied to a corresponding one of the first electrodes and the second electrode, the portion of the variable resistance layer pattern corresponding to an intersection region of the corresponding one of the first electrodes and the second electrode, the conductive path being substantially parallel to a top surface of the substrate.

12. The electronic device of claim 1, wherein the variable resistance layer pattern comprises a combination of two or more patterns and the combination exhibits variable resistance characteristics, and
wherein each of the two or more patterns is disposed substantially parallel to an outer sidewall of a corresponding one of the first electrodes.

13. The electronic device of claim 1, wherein the semiconductor memory further comprises a selection element layer sandwiched between the first electrodes and the variable resistance layer pattern, or between the second electrode and the variable resistance layer pattern.

14. The electronic device of claim 13, wherein the selection element layer is disposed substantially parallel to an outer sidewall of a corresponding one of the first electrodes.

15. The electronic device of claim 1, wherein the first base layer patterns comprise a material having a higher etch rate than the first electrodes.

16. The electronic device according to claim 1, further comprising a microprocessor which includes:
a control unit configured to receive a signal including a command from an outside of the microprocessor, and performs extracting, decoding of the command, or controlling input or output of a signal of the microprocessor;
an operation unit configured to perform an operation based on a result that the control unit decodes the command; and
a memory unit configured to store data for performing the operation, data corresponding to a result of performing the operation, or an address of data for which the operation is performed,
wherein the semiconductor memory is part of the memory unit in the microprocessor.

17. The electronic device according to claim 1, further comprising a processor which includes:
a core unit configured to perform, based on a command inputted from an outside of the processor, an operation corresponding to the command, by using data;
a cache memory unit configured to store data for performing the operation, data corresponding to a result of performing the operation, or an address of data for which the operation is performed; and
a bus interface connected between the core unit and the cache memory unit, and configured to transmit data between the core unit and the cache memory unit,
wherein the semiconductor memory is part of the cache memory unit in the processor.

18. The electronic device according to claim 1, further comprising a processing system which includes:
a processor configured to decode a command received by the processor and control an operation for information based on a result of decoding the command;
an auxiliary memory device configured to store a program for decoding the command and the information;
a main memory device configured to call and store the program and the information from the auxiliary memory device such that the processor can perform the operation using the program and the information when executing the program; and
an interface device configured to perform communication between at least one of the processor, the auxiliary memory device and the main memory device and the outside,
wherein the semiconductor memory is part of the auxiliary memory device or the main memory device in the processing system.

19. The electronic device according to claim 1, further comprising a data storage system which includes:
a storage device configured to store data and conserve stored data regardless of power supply;
a controller configured to control input and output of data to and from the storage device according to a command inputted form an outside;
a temporary storage device configured to temporarily store data exchanged between the storage device and the outside; and
an interface configured to perform communication between at least one of the storage device, the controller and the temporary storage device and the outside,
wherein the semiconductor memory is part of the storage device or the temporary storage device in the data storage system.

20. The electronic device according to claim 1, further comprising a memory system which includes:
a memory configured to store data and conserve stored data regardless of power supply;
a memory controller configured to control input and output of data to and from the memory according to a command inputted form an outside;
a buffer memory configured to buffer data exchanged between the memory and the outside; and
an interface configured to perform communication between at least one of the memory, the memory controller and the buffer memory and the outside,
wherein the semiconductor memory is part of the memory or the buffer memory in the memory system.
